(19) United States
(12) Patent Application Publication
(10) Pub. No.: US 2023/0422522 A1
(43) Pub. Date: Dec. 28, 2023

(54) SEMICONDUCTOR MEMORY DEVICE AND MANUFACTURING METHOD

(71) Applicant: Kioxia Corporation, Tokyo (JP)

(72) Inventor: Hisashi KATO, Yokkaichi Mie (JP)

(21) Appl. No.: 18/176,445

(22) Filed: Feb. 28, 2023

(30) Foreign Application Priority Data
Jun. 22, 2022 (JP) 2022-100704

(51) Int. Cl. H10B 80/00

(52) U.S. Cl. CPC H10B 80/00

(57) ABSTRACT

According to one embodiment, a semiconductor memory device includes a first chip and a second chip. The second chip is joined to the first chip at a first joining surface. The first chip includes a first memory cell array having a plurality of first memory cells. The first chip has a first wiring layer electrically connected to the first memory cell array. The second chip includes a second memory cell array that is electrically connected to the first wiring layer. The second memory cell array has a plurality of second memory cells. The second memory cell array shares the first wiring layer of the first chip with the first memory cell array. For example, the first wiring layer comprises bit lines which are shared by both the first and second memory cell arrays.

### CROSS-REFERENCE TO RELATED APPLICATION

This application is based upon and claims the benefit of priority from Japanese Patent Application No. 2022-100704, filed Jun. 22, 2022, the entire contents of which are incorporated herein by reference.

### FIELD

Embodiments described herein relate generally to a semiconductor memory device and a manufacturing method a semiconductor device.

### BACKGROUND

A semiconductor memory device, such as a NAND-type flash memory, may be configured by bonding memory chips together. Each of the memory chips includes a memory cell array and bit lines connected to the memory cell array. When a complementary metal oxide semiconductor (CMOS) circuit that controls the memory cell array is shared by the multiple memory chips, the bit lines of memory chips are all connected to the CMOS circuit, and thus a parasitic capacitance due to the bit lines increases. In addition, in order to selectively connect the bit lines of the memory chips to the CMOS circuit, a switch is required to be provided for each bit line. In this case, the miniaturization of the semiconductor memory device is prevented.

### BRIEF DESCRIPTION OF THE DRAWINGS

FIG. 1 is a cross-sectional view illustrating of a semiconductor memory device according to a first embodiment.

FIG. 2 is a plan view illustrating a first memory cell array or a second memory cell array according to a first embodiment.

FIG. 3 is a schematic cross-sectional view illustrating an example of a memory cell having a three-dimensional structure according to a first embodiment.

FIG. 4 is a schematic cross-sectional view illustrating an example of a memory cell having a three-dimensional structure according to the first embodiment.

FIG. 5 is a schematic plan view illustrating an enlarged portion of FIG. 2.

FIGS. 6 to 12 are schematic cross-sectional views illustrating aspects of a method for manufacturing a semiconductor memory device according to a first embodiment.

FIG. 13 is a cross-sectional view illustrating a configuration example of a semiconductor memory device according to a second embodiment.

FIG. 14 is a cross-sectional view illustrating a configuration example of a semiconductor memory device according to a third embodiment.

FIG. 15 is a block diagram illustrating a configuration example of a semiconductor memory device.

FIG. 16 is a circuit diagram illustrating an example of a circuit configuration of a memory cell array.

### DETAILED DESCRIPTION

Embodiments relate a semiconductor memory device with reduced capacitance of a bit line and a manufacturing method thereof. The semiconductor memory device of an embodiment is appropriate for improved miniaturization.

In general, according to one embodiment, a semiconductor memory device includes a first chip and a second chip. The first chip has a first memory cell array with a plurality of first memory cells. The first chip also has a first wiring layer electrically connected to the first memory cell array. The second chip has a second memory cell array that is electrically connected to the first wiring layer. The second memory cell array has a plurality of second memory cells. The second chip is joined to the first chip at a first joining surface. The second memory cell array shares the first wiring layer of the first chip with the first memory cell array.

Hereinafter, certain example embodiments according to the present disclosure will be described with reference to the drawings. These example embodiments do not limit the present disclosure. The drawings are schematic or conceptual, and the depicted dimensions, relationships between parts, ratios and the like of the depicted components are not necessarily the same as those in an actual implementation of the present disclosure. In the specification and drawings, the same reference symbols are given to the same elements and additional description thereof may omitted as appropriate after an initial description.

### FIRST EMBODIMENT

### Configuration of Semiconductor Memory device 100

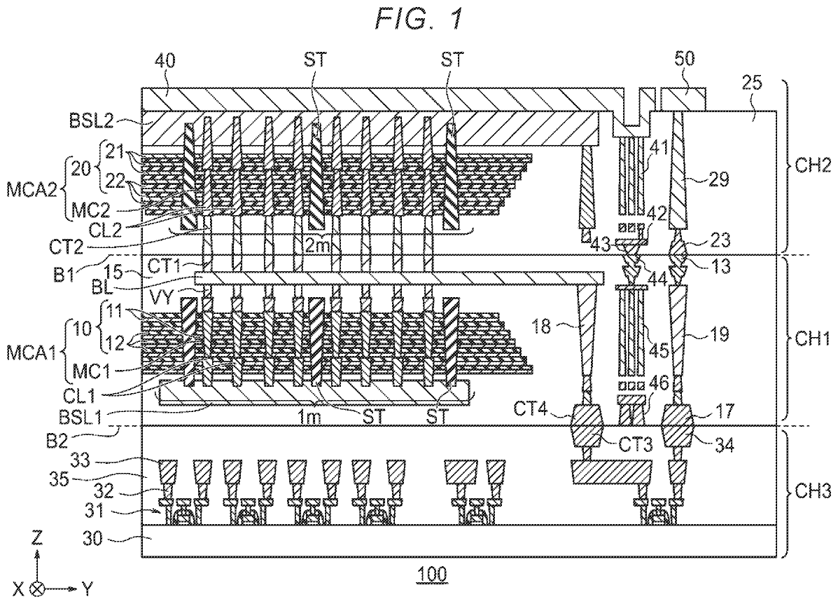

FIG. 1 is a cross-sectional view illustrating a

configuration example of a semiconductor memory device 100 according to a first embodiment. Hereinafter, a stacking direction of a first array chip CH1 and a second array chip CH2 is referred to as a Z direction. One direction that intersects the Z direction is referred to as a Y direction. One direction that intersects the Z direction and the Y direction is referred to as an X direction.

The semiconductor memory device 100 includes the first array chip CH1 and the second array chip CH2 each having a memory cell array, and a CMOS chip CH3 having a CMOS circuit. The first array chip CH1 is an example of a first chip, the second array chip CH2 is an example of a second chip, and the CMOS chip CH3 is an example of a third chip.

The first array chip CH1 and the second array chip CH2 are bonded to each other on a bonding surface B1 (bonding interface). The bonding surface B1 is an example of a first joining surface. The first array chip CH1 and the CMOS chip CH3 are bonded to each other on a bonding surface B2 (bonding interface). The bonding surface B2 is an example of a second joining surface. FIG. 1 illustrates a state in which the first array chip CH1 has been bonded onto the CMOS chip CH3, and the second array chip CH2 has been bonded onto the first array chip CH1.

The CMOS chip CH3 includes a substrate 30, transistors 31 (transistor level), vias 32, a wiring 33 (a wiring level), an interlayer insulating film 35, a pad CT3, and a pad 34.

The substrate 30 is, for example, a semiconductor substrate such as a silicon substrate. The transistors 31 can be an NMOS or PMOS transistor provided on the substrate 30. The transistors 31 configure, for example, CMOS circuits that control memory cell arrays of the first array chip CH1 and the second array chip CH2. A semiconductor element such as a resistance element (resistor) and a capacitive element (capacitor) other than the transistors 31 may also be formed on the substrate 30.

An electrical connection between the transistors 31 and the wiring 33 or between the wiring 33 and the pads CT3 and 34 is made by the vias 32. The wiring 33 and the pads CT3 and 34 form a multilayer wiring structure in the interlayer insulating film 35. The pads CT3 and 34 are embedded in the interlayer insulating film 35, and exposed to be substantially flush with a surface of the interlayer insulating film 35. The wiring 33 and the pads CT3 and 34 are electrically connected to the transistors 31 or the like. The pads CT3 and 34 are both examples of a third pad. For example, a low-resistance metal such as copper or tungsten is used for the via 32, the wiring 33, and the pads CT3 and 34. The pads CT3 and 34 are electrically connected respectively to a pad CT4 and a pad 17 of the first array chip CH1 on the bonding surface B2. The pads CT4 and 17 of the first array chip CH1 are both examples of a fourth pad. The interlayer insulating film 35 covers and protects the transistors 31, the vias 32, the wiring 33, and the pads CT3 and 34. For the interlayer insulating film 35, for example, an insulating film such as a silicon oxide film is used.

The first array chip CH1 includes a stacked body 10, a first columnar body CL1, a source layer BSL1, contact plugs 18, 19, and 45, a bit line BL, pads CT1, CT4, 17, 44, and 46, and an interlayer insulating film 15.

The stacked body 10 is provided above the substrate and the transistor 31 (in the Z direction). The stacked body is configured by alternately stacking a plurality of electrode films 11 and a plurality of insulating films 12 in the Z direction. For the electrode film 11, for example, a conductive metal such as tungsten is used. For the insulating film 12, for example, an insulating material such as a silicon oxide film is used. The insulating film 12 insulates the electrode films 11 from each other. That is, the plurality of electrode films 11 are stacked in an insulating state from each other. The number of stacked electrode films 11 and the number of stacked insulating films 12 may be any number. The insulating film 12 may be, for example, a porous insulating film or an air gap in some examples.

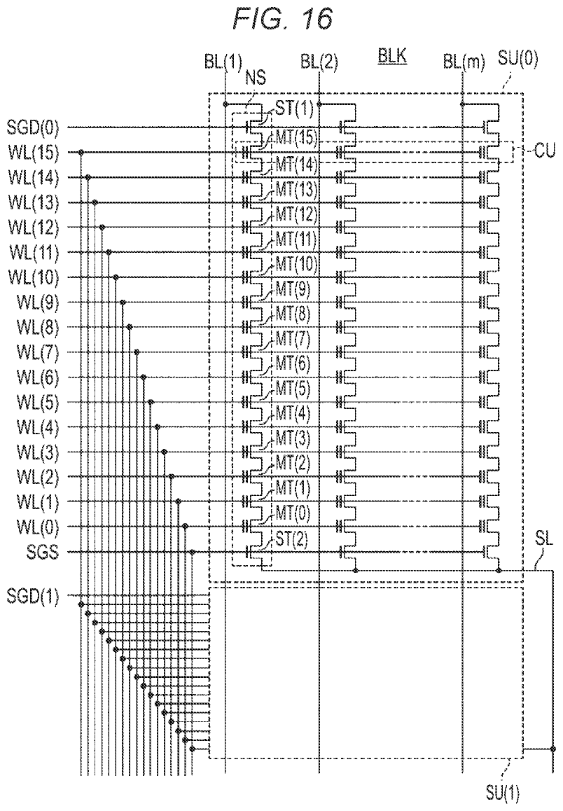

As illustrated in FIG. 16, one or more of electrode films 11 at an upper end and a lower end of the stacked body 10 in the Z direction function as a source-side select gate SGS and a drain-side select gate SGD, respectively. The electrode films 11 between the source-side select gate SGS and the drain-side select gate SGD functions as a word line WL. A word line WL is a gate electrode of a first memory cell array MCA1. A drain-side select gate SGD is a gate electrode of a drain-side select transistor STD. A source-side select gate SGS is a gate electrode of a source-side select transistor STS.

The semiconductor memory device 100 of FIG. 1 has a plurality of memory cells MC1 connected in series, between a source-side select transistor and a drain-side select transistor. This plurality of memory cells MC1 configure the first memory cell array MCA1. The structure in which the source-side select transistor, the memory cells MC1, and the drain-side select transistor are connected to each other in series is referred to as a “memory string” or a “NAND string”. The memory string is electrically connected to a bit line BL. The bit line BL is provided above the stacked body 10 and extends in the Y direction. The bit lines BL are an example of the first wiring layer. According to the present embodiment, the bit lines BL are shared between the first memory cell array MCAT and a second memory cell array MCA2.

A plurality of columnar bodies CL1 are provided in the stacked body 10. The columnar bodies CL1 extend to penetrate the stacked body 10 in a stacking direction of the electrode films 11 and the insulating films 12 (in the Z direction) in the stacked body 10 and are provided from the bit line BL to the source layer BSL1. The memory cells MC1 are provided at the intersections between the columnar bodies CL1 and the electrode films 11. The plurality of memory cells MC1 are three-dimensionally located to configure the first memory cell array MCA1. The internal structure of the columnar body CL1 is described below. In addition, according to the present embodiment, the columnar bodies CL1 have a high aspect ratio and thus must be formed in two stages in the Z direction. However, in other examples, the columnar bodies CL1 may be formed in a single stage and the number of stages is not a limitation.

In addition, a plurality of slits ST are provided in the stacked body 10. The slits ST extend in the X direction and penetrate the stacked body 10 in the Z direction. The inside of the slit ST is filled with an insulating film such as a silicon oxide film, and thus the insulating film is configured in the plate shape. The slits ST electrically isolate the electrode films 11 of the stacked body 10. Wiring may be provided in the insulating film in the slit ST. This wiring may be connected to the source layer BSL1 while electrical insulation from the electrode film 11 is maintained.

The bit lines BL are provided above the stacked body 10. A plurality of columnar bodies CL1 are electrically connected below the same bit line BL (the CMOS chip CH3 side) via vias VY. The pads CT1 are electrically connected above the bit line BL (the second array chip CH2 side). The pad CT1 is an example of a first pad. The pads CT1 are electrically connected to the first memory cell array MCAT via the bit line BL. The pads CT1 are embedded in the interlayer insulating film 15 and exposed to be substantially flush with a surface of the interlayer insulating film 15. In addition, the pads CT1 are electrically connected to pads CT2 of the second array chip CH2. The bit line BL is electrically connected to a contact plug 18. The contact plug 18 is connected to the CMOS chip CH3 via the pad CT4. The bit line BL is thus also electrically connected to the CMOS chip CH3 via the contact plug 18.

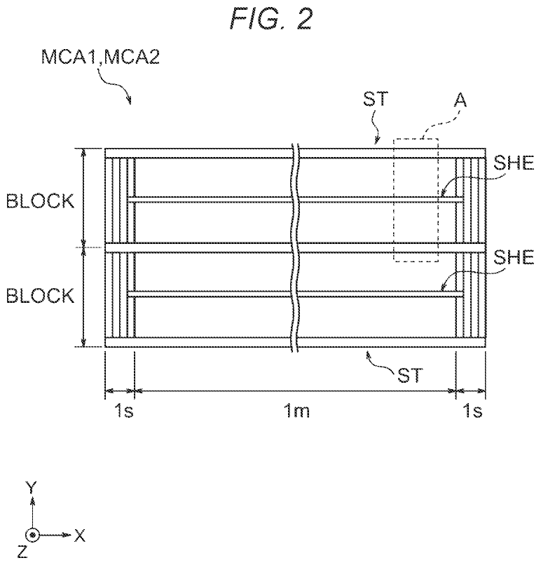

The source layer BSL1 is provided below the stacked body 10. The source layer BSL1 is provided corresponding in position to the stacked body 10. One end of the columnar bodies CL1 is commonly connected above the source layer BSL1 (the first memory cell array MCA1 side). Accordingly, the source layer BSL1 applies a common source voltage to the plurality of columnar bodies CL1 in the first memory cell array MCA1 and functions as a common source electrode of the first memory cell array MCA1. For the source layer BSL1, for example, a conductive material such as doped polysilicon is used. In addition, a part lm of the first memory cell array MCA1 is a part of a memory cell array, and parts is of the first memory cell array MCA1 are step parts of the electrode film 11 provided to permit a contact to be connected to each electrode film 11 individually. The part lm and the parts is are described below with reference to FIG. 2.

A contact plug 19 extends in the interlayer insulating film 15 in the Z direction. One end of the contact plug 19 is electrically connected to the pad 34 of the CMOS chip CH3 via the pad 17. The other end of the contact plug 19 is electrically connected to a pad 23 of the second array chip CH2 via a pad 13.

The second array chip CH2 includes a stacked body 20, second columnar bodies CL2, a source layer BSL2, contact plugs 29 and 41, a conductor 42, a pad CT2, a pad 43, a metal layer 40, a bonding pad 50, and an interlayer insulating film 25.

The configurations of the stacked body 20, the second columnar bodies CL2, and the source layer BSL2 are generally the same as those of the stacked body 10, the first columnar bodies CL1, and the source layer BSL1, respectively.

The source layer BSL2 is provided above the stacked body 20, and the metal layer 40 is provided above the source layer BSL2. The metal layer 40 includes, for example, a source line or a power line, and a metal material such as copper, tungsten, or aluminum is used. The source layer BSL2 and the metal layer 40 are electrically connected to each other. The bonding pad 50 is also provided above the source layer BSL2. The bonding pad 50 may receive the power supply from the outside of the semiconductor memory device 100. The bonding pad 50 is connected to the pad 34 of the CMOS chip CH3 via the contact plugs 29 and 19, the pads 13, 23, and 17, and the like. Accordingly, the external power supplied from the bonding pad 50 is supplied to the CMOS chip CH3.

The pads CT2 are provided below the stacked body 20. Each pad CT2 is an example of a second pad. The pads CT2 are connected to the plurality of second columnar bodies CL2. Accordingly, the pads CT2 are electrically connected to the second memory cell array MCA2. The pads CT2 are embedded in the interlayer insulating film 25 and exposed to be substantially flush with a surface of the interlayer insulating film 25. As described above, the pads CT2 are electrically connected to the pads CT1 of the first array chip CH1 on the bonding surface B1.

Below the second array chip CH2, the pad 43 is electrically connected to the upper surface of the pad 44. The pad 43 is electrically connected to the metal layer 40 provided on an upper surface of the source layer BSL2 via the conductor 42 and the contact plug 41. In the first array chip CH1, the pad 44 is electrically connected to the CMOS chip CH3 via the contact plug 45 and the pad 46. Although details are not illustrated, the pad 46 is electrically connected to the transistor 31 via a contact or a conductor. Accordingly, the metal layer 40 provided on the upper surface of the source layer BSL2 is electrically connected to the transistor 31.

Here, the sharing of a bit line BL by the first memory cell array MCA1 and the second memory cell array MCA2 is described.

The columnar bodies CL1 of the first memory cell array MCA1 are electrically connected to the bit lines BL via the vias VY. In addition, the second columnar bodies CL2 of the second memory cell array MCA2 are connected to the bit lines BL via the pads CT2 and the pads CT1. That is, each bit line BL is commonly connected to, and shared by, the first memory cell array MCA1 and the second memory cell array MCA2. That is, bit lines BL on a single device layer are provided for two stacked memory cell arrays. The bit lines BL are provided inside the first array chip CH1, but not in the second array chip CH2. When illustrated in FIG. 1, as viewed from the X direction, the bit lines BL on the same (single) layer appears as one wiring, but in fact a plurality of bit lines BL are located spaced one form the other in the X direction as would be apparent when viewed from the Z direction in a plan view.

According to the present embodiment, when a bit line BL is shared by the two array chips CH1 and CH2, the total extension or total deposition of the bit lines BL is shorter or smaller by one layer, compared with when the bit line BL is not shared. Accordingly, the parasitic capacitance of the bit line BL can be reduced. In addition, the sharing of the bit line BL by the two array chips CH1 and CH2 leads to the miniaturization of the semiconductor memory device 100.

According to the present embodiment, the first array chip CH1, the second array chip CH2, and the CMOS chip CH3 are individually formed and bonded to each other. The CMOS chip CH3 is shared by the array chips CH1 and CH2 as a memory controller or peripheral circuit that controls the memory cell arrays MCA1 and MCA2.

FIG. 2 is a schematic plan view illustrating the first memory cell array MCA1 or the second memory cell array MCA2. In FIG. 2, the configuration of the first memory cell array MCA1 is described. The second memory cell array MCA2 may have the same configuration.

The first memory cell array MCA1 includes the parts is and the part 1m. The parts 1s are provided stepwise at the edge portions of the first memory cell array MCA1. The part 1m is interposed between or surrounded by the parts 1s. The slits ST are provided from the part is at one end of the first memory cell array MCAT to the part is at the other end of the first memory cell array MCAT through the part 1m. Slits SHE are provided at least in the part 1m. The slits SHE are shallower than the slits ST and extend substantially parallel to the slits ST. The slits SHE are provided for electrically isolating the electrode films 11 per drain-side select gate SGD.

The part of the first memory cell array MCAT interposed between the two adjacent slits ST as illustrated in FIG. 2 is referred to as a block. The block typically is a minimum unit for erasing data. The slits SHE are provided in each block. The portion of the first memory cell array MCAT between a slit ST and a slit SHE is referred to as a finger. The drain-side select gate SGD is separated (divided) as fingers. Therefore, when writing and reading data, one finger in the block can be selected by the drain-side select gate SGD.

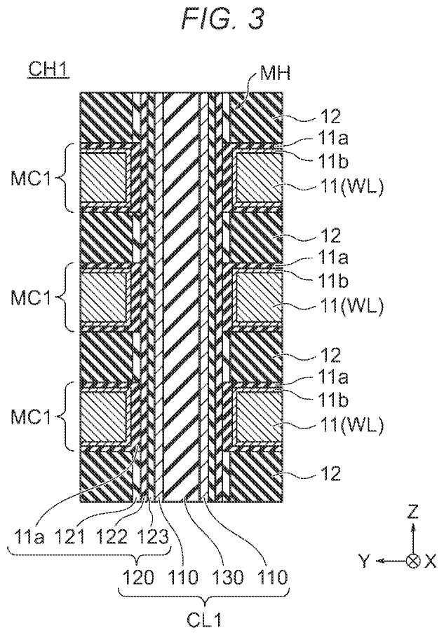

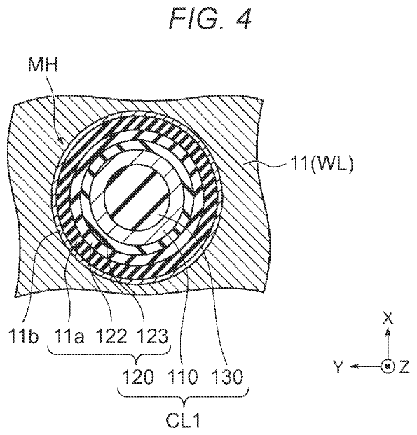

FIGS. 3 and 4 each are schematic cross-sectional views illustrating examples of the memory cell having a three-dimensional structure. In FIGS. 3 and 4, the configuration of a columnar body CL1 is described. The columnar body CL2 may have substantially the same configuration.

As illustrated in FIG. 3, the columnar bodies CL1 each are provided in a memory hole MH provided in the stacked body 10.

Each of the columnar bodies CL1 penetrates from the upper end to the lower end of the stacked body 10 in the Z direction and is provided in the stacked body 10 and throughout the source layer BSL1. The columnar bodies CL1 each include a semiconductor body 110, a memory film 120, and a core layer 130. The columnar body CL1 includes the core layer 130 provided in the central portion thereof, the semiconductor body 110 (semiconductor member) provided around the core layer 130, and the memory film 120 (charge storage member) provided around the semiconductor body 110. The semiconductor body 110 extends in a stacking direction (in the Z direction) in the stacked body 10. The semiconductor body 110 is electrically connected to the source layer BSL1. The memory film 120 is provided between the semiconductor body 110 and the electrode films 11 and includes a charge trapping portion. The columnar bodies CL1 selectable one by one from each finger are commonly connected to the same bit line BL. The columnar bodies CL1 each are provided, for example, in the area of the part 1m.

As illustrated in FIG. 4, the shape of the memory hole MH in the X-Y plane is, for example, a circle or an ellipse. A block insulating film 11a that configures a part of the memory film 120 is provided between the electrode film 11 and the insulating film 12. The block insulating film 11a is, for example, a silicon oxide film or a metal oxide film. One example of metal oxide is aluminum oxide. A barrier film 11b is provided between the electrode film 11 and the insulating film 12 and between the electrode film 11 and the memory film 120. When the electrode film 11 is tungsten, for example, a stacked structure film of titanium nitride (TiN) and titanium (Ti) is selected as the barrier film 11b. The block insulating film 11a prevents back tunneling of charges from the electrode film 11 to the memory film 120 side. The barrier film 11b improves adhesion between the electrode film 11 and the block insulating film 11a.

The shape of the semiconductor body 110 is a cylindrical shape. For example, polysilicon is used for the semiconductor body 110. In some examples, semiconductor body 110 is undoped silicon. In other examples, the semiconductor body 110 may be p-type silicon. The semiconductor body 110 becomes a channel for each of the drain-side select transistor STD, the memory cells MC1, and the source-side select transistor STS. One end of the semiconductor bodies 110 in the same part lm are electrically commonly connected to the source layer BSL1.

In the memory film 120, a part other than the block insulating film 11a can be provided between the inner wall of the memory hole MH and the semiconductor body 110. The shape of the memory film 120 is, for example, a cylindrical shape. The plurality of memory cells MC1 include storage areas between the semiconductor body 110 and the electrode films 11 (those functioning as word lines WL) and are stacked in the Z direction. The memory film 120 includes, for example, a cover insulating film 121, a charge trapping film 122, and a tunnel insulating film 123. The semiconductor body 110, the charge trapping film 122, and the tunnel insulating film 123 each extend in the Z direction.

The cover insulating film 121 is provided between the insulating film 12 and the charge trapping film 122. The cover insulating film 121 includes, for example, silicon oxide. The cover insulating film 121 keeps the charge trapping film 122 from being etched in a replacement step when the electrode film 11 is replacing a sacrificial film temporarily present during initial manufacturing stages of the memory cell array. The cover insulating film 121 may also be removed from a portion between the electrode films 11 and the memory film 120 in the replacement step. In this case, as illustrated in FIGS. 3 and 4, the block insulating film 11a is not provided between the electrode films 11 and the charge trapping film 122. In addition, when the replacement step is not used for forming the electrode films 11, the cover insulating film 121 need not be provided.

The charge trapping film 122 is provided between the block insulating film 11a and the cover insulating film 121, and the tunnel insulating film 123. The charge trapping film 122 includes, for example, silicon nitride (SiN) and has trap sites that trap charges in the film. A part of the charge trapping film 122 interposed between the electrode films 11 (which will be the word lines WL) and the semiconductor body 110 configures the storage area of the memory cell MC1 as the charge trapping portion. A threshold voltage of the memory cell MC1 changes depending on whether there are charges in the charge trapping portion or the amount of charges trapped in the charge trapping portion. Accordingly, the memory cell MC1 stores information (data).

The tunnel insulating film 123 is provided between the semiconductor body 110 and the charge trapping film 122. The tunnel insulating film 123 includes, for example, silicon oxide or silicon oxide and silicon nitride. The tunnel insulating film 123 is a potential barrier between the semiconductor body 110 and the charge trapping film 122. For example, when electrons are injected from the semiconductor body 110 to the charge trapping portion (a write operation), or when holes are injected from the semiconductor body 110 to the charge trapping portion (an erasing operation), the electrons and the holes each pass through the potential barrier of the tunnel insulating film 123 (tunneling).

The core layer 130 is embedded in the internal space of the cylindrical semiconductor body 110. The shape of the core layer 130 is, for example, a columnar shape. The core layer 130 includes, for example, silicon oxide and is an insulating material.

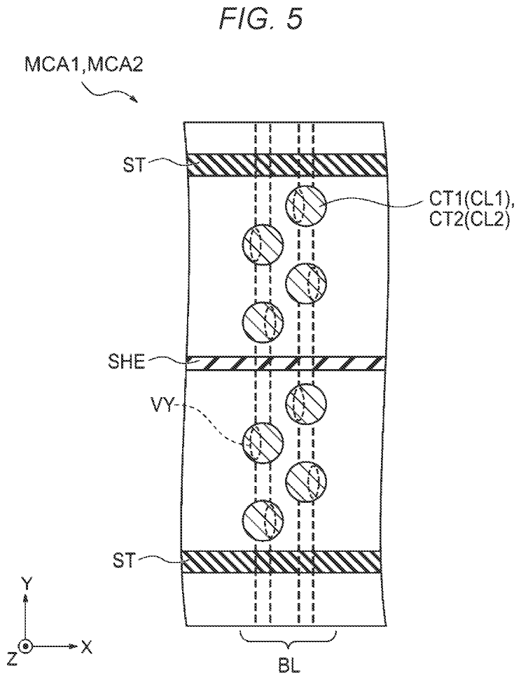

FIG. 5 is a schematic plan view illustrating a configuration example of the first array chip CH1. FIG. 5 illustrates an enlarged area A of FIG. 2. FIG. 5 illustrates the bit lines BL (four are depicted) , the vias VY (eight are depicted), and the pads CT1 (eight for the columnar bodies CL1 are depicted), in addition to the slits ST and the slit SHE. The array chip CH1 includes the bit lines BL, but the second array chip CH2 is different from the first array chip CH1 in that the bit lines BL are not provided. The other configurations of the second array chip CH2 may be substantially the same as those of the first array chip CH1.

The plurality of columnar bodies CL1 are located, for example, in a zigzag pattern in the area between adjacent slits ST. The number or the arrangement of the columnar bodies CL1 between the adjacent slits ST is not limited to these examples and may be appropriately changed. As described above, each of the columnar bodies CL1 functions as a memory string. The plurality of bit lines BL each extend in the Y direction and are spaced in the X direction. The bit lines BL overlap with columnar bodies CL1. According to the present embodiment, two bit lines BL overlap with each of the columnar bodies CL1.

In each finger between the slit ST and the slit SHE or between the adjacent slits SHE, each of the columnar bodies CL1 is connected to one bit line BL via the via VY. That is, in each finger, there is a one-to-one correspondence between the number of columnar bodies CL1 and the number of bit lines BL. Thus, when one finger is selected, the plurality of bit lines BL can transmit data read from all the columnar bodies CL1 in the corresponding finger, respectively.

The pad CT1 is provided above the bit line BL (in the Z direction) and electrically connected to the bit line BL. Accordingly, in a plan view in the Z direction, the pads CT1 overlap with the columnar bodies CL1 at substantially the same positions.

In addition, in the second array chip CH2, the arrangement of the plurality of columnar bodies CL2 may be the same as the arrangement of the plurality of columnar bodies CL1. That is, in a plan view in the Z direction, the pads CT2 overlap with the columnar body CL2 at substantially the same positions. In addition, the second array chips CH2 share the bit lines BL with the first array chips CH1. Accordingly, in a plan view in the Z direction, the arrangement relationship between the columnar bodies CL2 or the pads CT2 and the bit lines BL is the same as that between the columnar bodies CL1 or the pads CT1 and the bit line BL of FIG. 5. Accordingly, in a plan view in the Z direction, the pads CT2 and the columnar bodies CL2 of the second array chip CH2 and the pads CT1 and the columnar bodies CL1 of the first array chip CH1 are positioned at substantially the same positions and overlap with each other.

With the above, in FIG. 5, the columnar bodies CL1, the pads CT1, the columnar bodies CL2, and the pads CT2 all are at substantially the same positions in plan view. Accordingly, each bit line BL is commonly connected to one of the plurality of columnar bodies CL1 and one of the plurality of columnar bodies CL2. That is, the first memory cell array MCAT and the second memory cell array MCA2 share the bit lines BL.

Method for Manufacturing Semiconductor Memory Device 100

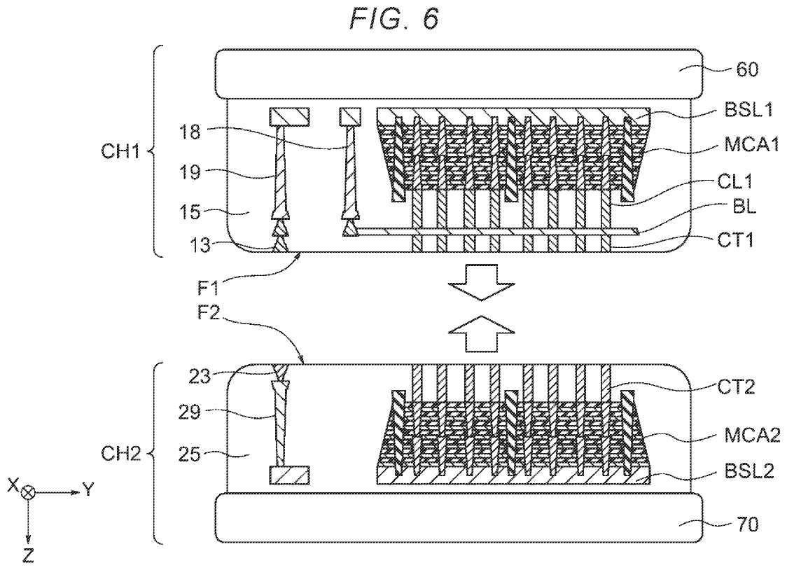

The method for manufacturing the semiconductor memory device 100 is described with reference to FIGS. 6 to 12. FIGS. 6 to 12 are schematic cross-sectional views illustrating examples of the method for manufacturing the semiconductor memory device 100 according to the present embodiment.

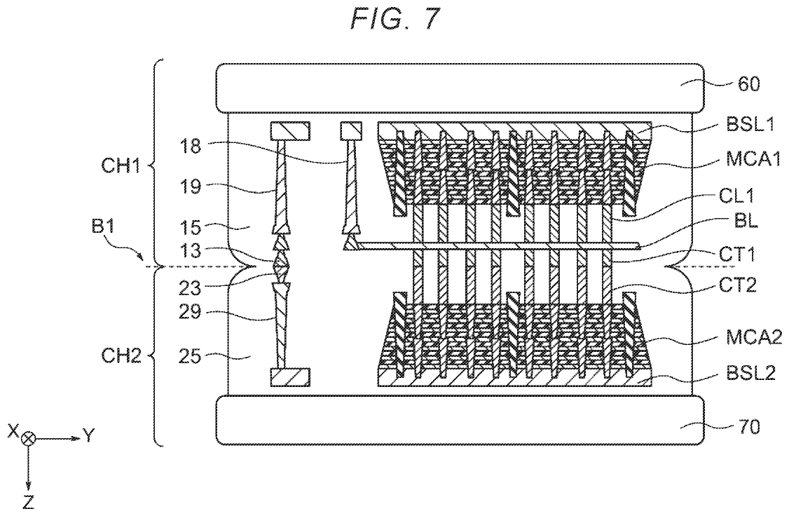

First, as illustrated in FIGS. 6 and 7, in a step of manufacturing a semiconductor memory chip, the first array chip CH1 and the second array chip CH2 are manufactured.

The source layer BSL1, the first memory cell array MCAT (the first memory cell MC1), the bit line BL, the pads CT1 and 13, the contact plug 19, and the like are formed above a substrate 60 and covered with the interlayer insulating film 15 to manufacture the first array chip CH1. Similarly, the source layer BSL2, the second memory cell array MCA2 (a second memory cell MC2), the pads CT2 and 23, the contact plug 29, and the like are formed above a substrate 70 and covered with the interlayer insulating film 25 to manufacture the second array chip CH2.

At this time, the pads CT1 and 13 are exposed to be substantially flush with a surface F1 of the first array chip CH1. In addition, the pads CT2 and 23 are exposed to be substantially flush with a surface F2 of the second array chip CH2. Accordingly, when the first array chip CH1 and the second array chip CH2 are bonded to each other, the pads CT1 and the pads CT2 are electrically connected to each other, and the pad 13 and the pad 23 are electrically connected to each other.

FIG. 7 illustrates a state after the first array chip CH1 and the second array chip CH2 are bonded to each other. The first array chip CH1 and the second array chip CH2 are bonded on the bonding surface B1. On the bonding surface B1, the pads CT1 and the pads CT2 are electrically connected to each other, and the pad 13 and the pad 23 are electrically connected to each other. In addition, the bit line BL is connected to the first memory cell array MCA1 via the columnar bodies CL1. In addition, the bit line BL is connected to the second memory cell array MCA2 via the pads CT1 and the pads CT2. In this manner, the bit line BL is commonly connected to the first memory cell array MCA1 and the second memory cell array MCA2.

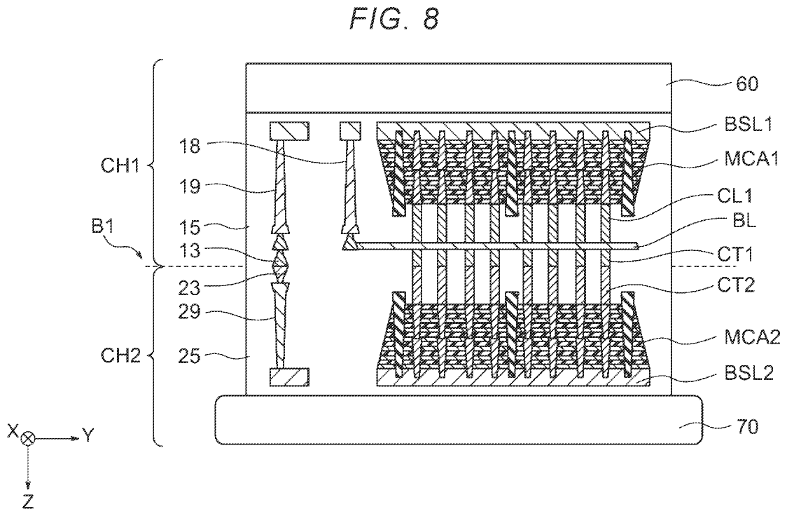

Next, as illustrated in FIG. 8, excess parts of the edge portions of the substrate 60, the substrate 70, the interlayer insulating film 15, and the interlayer insulating film 25 are removed (trimmed) by using a dicing blade. According to the present embodiment, the first array chip CH1 and the second array chip CH2 are bonded to each other and then trimmed. Accordingly, the excess parts of both the first array chip CH1 and the second array chip CH2 can be removed by trimming once, and thus the manufacturing step may be simplified.

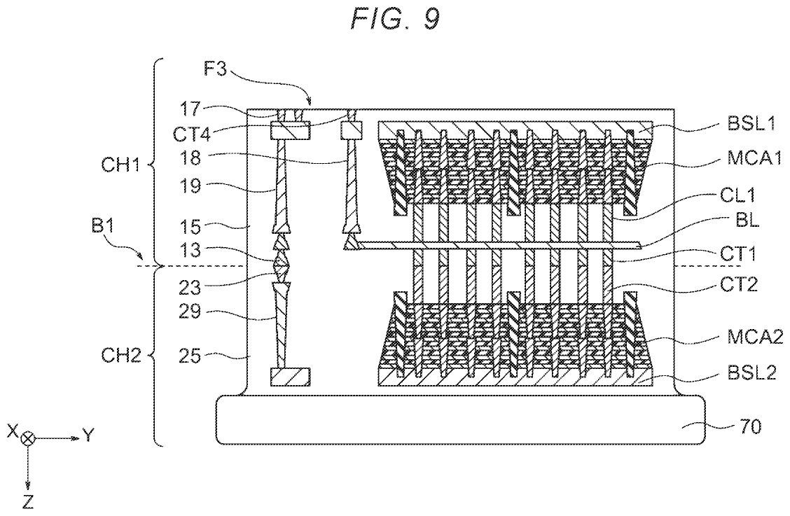

Next, as illustrated in FIG. 9, the substrate 60 is peeled off (removed) to expose a surface F3. Further, by using lithography technology and etching technology, contact holes are formed in the interlayer insulating film 15. The contact holes are formed to a depth reaching the source layer BSL1 of the first memory cell array MCA1. Next, a metal material such as copper is embedded in the corresponding contact holes to form the pads CT4 and 17.

Next, by using a chemical mechanical polishing (CMP) method, the interlayer insulating film 15 may be polished so that the pads CT4 and 17 are exposed to be substantially flush with the surface F3.

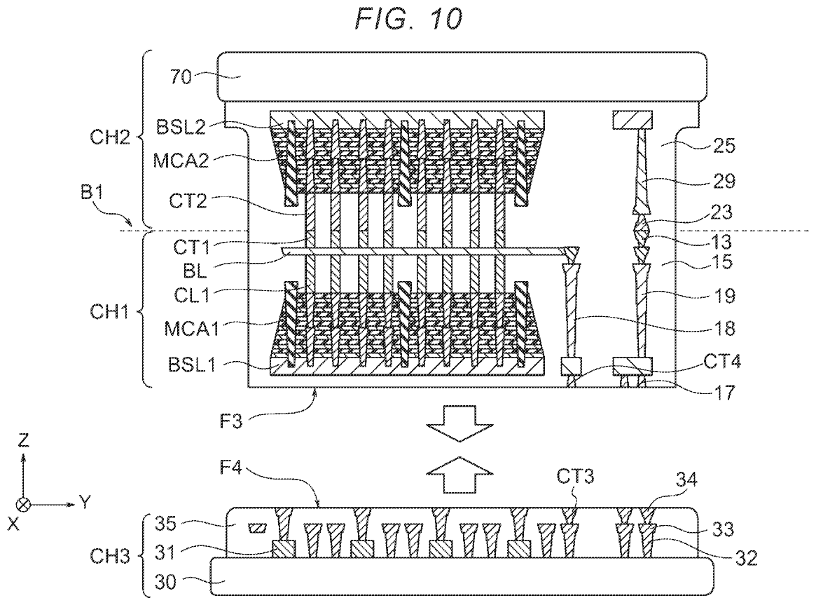

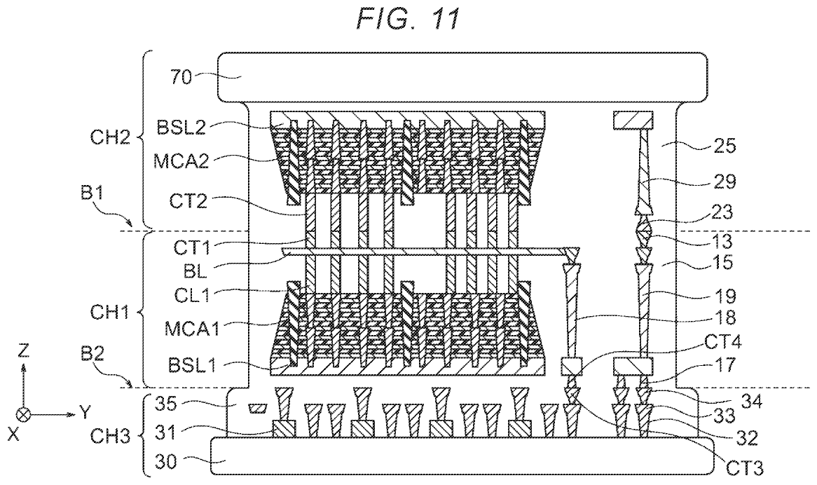

Next, as illustrated in FIGS. 10 and 11, the CMOS chip CH3 is manufactured by using a semiconductor manufacturing process. The transistor 31, the via 32, the wiring 33, and the pads CT3 and 34 are formed above the substrate 30 and protected by the interlayer insulating film 35 to manufacture the CMOS chip CH3. In addition, the pads CT3 and 34 are exposed to be substantially flush with a surface F4. Next, the array chips CH1 and CH2 are turned upside down to bond the surface F3 of the first array chip CH1 and the surface F4 of the CMOS chip CH3.

FIG. 11 illustrates a state after the first array chip CH1 and the CMOS chip CH3 are bonded to each other. The first array chip CH1 and the CMOS chip CH3 are bonded on the bonding surface B2. On the bonding surface B2, the pad CT4 and the pad CT3 are electrically connected to each other, and the pad 17 and the pad 34 are electrically connected to each other. In addition, the bit lines BL are electrically connected to the substrate 30 of the CMOS chip CH3 via the transistor.

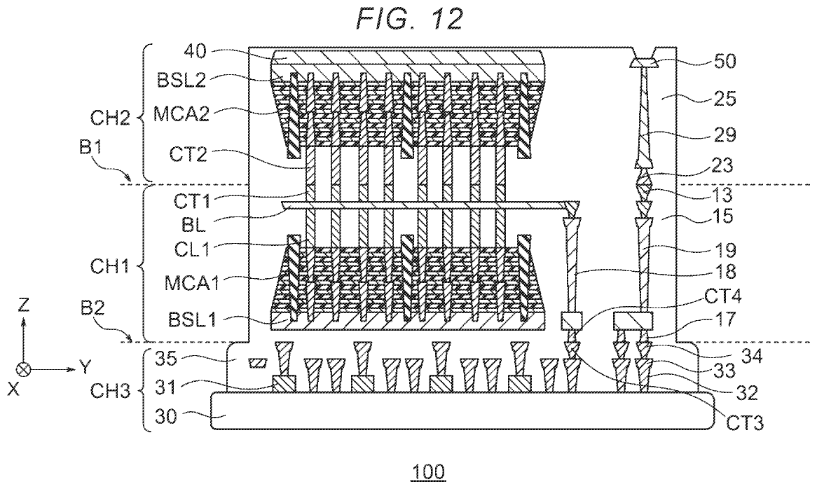

Next, as illustrated in FIG. 12, the substrate 70 is peeled off (removed). Next, a metal material such as aluminum is embedded in the interlayer insulating film 25 to form the metal layer 40 and the bonding pad 50. The bonding pad 50 is connected to the contact plug 29. Accordingly, the bonding pad 50 is electrically connected to the CMOS chip CH3. Thereafter, the bonding pad 50 can be fragmented for each chip of the semiconductor memory device 100 by a dicing step. With the above steps, the semiconductor memory device 100 according to the present embodiment is manufactured.

With the above, according to the present embodiment, a bit line BL is commonly connected to (shared by) the first memory cell array MCA1 and the second memory cell array MCA2. Accordingly, the bit lines BL of one layer may be provided corresponding to two memory cell arrays, and thus it is possible to prevent the bit lines BL from being multilayered. When the bit lines BL are shared in this manner, the total extension (length) of the bit lines BL can be shortened and also the parasitic capacitance thereof can be reduced. Accordingly, the operating speed of the semiconductor memory device 100 can be increased, and also the power consumption of the semiconductor memory device 100 can be reduced. In addition, the bit line BL is shared by the two memory cell arrays MCA1 and MCA2, and thus the semiconductor memory device 100 is miniaturized.

In addition, the bit line BL is shared by the two memory cell arrays MCA1 and MCA2, and thus a switch (transistor) for selecting among the different bit lines BL for different stacked memory cell arrays is not required. Accordingly, the transistor for selecting the bit line BL can be omitted. Accordingly, the semiconductor memory device 100 is miniaturized.

In addition, the first array chip CH1 and the second array chip CH2 are bonded to each other and then trimmed.

Therefore, the excess parts of the first array chip CH1 and the second array chip CH2 can be removed by trimming once, and thus the manufacturing step can be simplified.

### SECOND EMBODIMENT

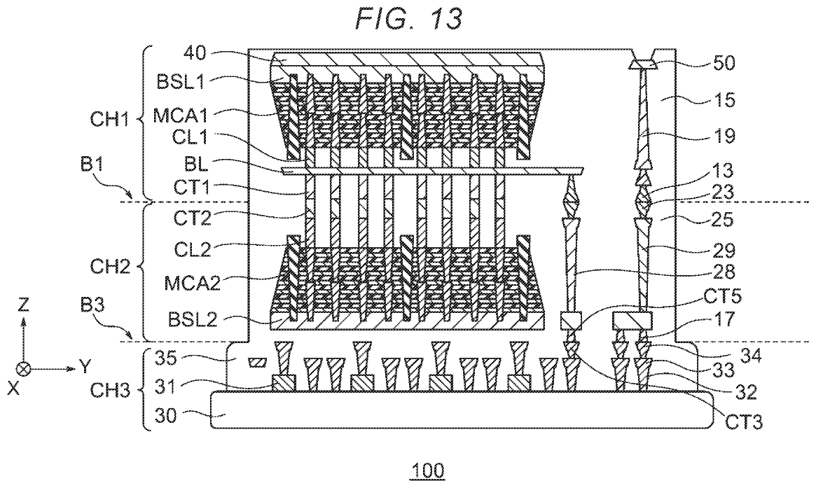

FIG. 13 is a cross-sectional view illustrating a configuration example of the semiconductor memory device 100 according to a second embodiment. The second embodiment is different from the first embodiment in that the CMOS chip CH3 is bonded to the second array chip CH2 in which the bit line BL is not provided. In addition, the metal layer 40 and the bonding pad 50 are provided in the first array chip CH1. The other configurations of the second embodiment may be the same as those of the first embodiment.

The second array chip CH2 includes a pad CT5 on a surface opposite to the bonding surface B1. The pad CT5 is embedded in the interlayer insulating film 25 and exposed to be substantially flush with a surface of the interlayer insulating film 25. The pad CT5 is an example of a fifth pad. The pad CT5 is electrically connected to the pad CT3 of the CMOS chip CH3 on a bonding surface B3 (bonding interface). The bonding surface B3 is an example of a third joining surface. Accordingly, the second memory cell array MCA2 and the CMOS chip CH3 are electrically connected to each other via the pads CT5 and CT3. A contact plug 28 is electrically connected to the bit line BL. In addition, the contact plug 28 is connected to the CMOS chip CH3 via the pads CT5 and CT3. Accordingly, the bit line BL is electrically connected to the CMOS circuit of the CMOS chip CH3.

The other configurations of the second embodiment may be the same as those of the first embodiment. Therefore, according to the second embodiment, the first memory cell array MCA1 and the second memory cell array MCA2 are commonly connected to the bit lines BL. Therefore, the second embodiment can obtain substantially the same effect as the first embodiment. The manufacturing method for the second embodiment is readily apparent from the described manufacturing method according to the first embodiment. The manufacturing method according to the second embodiment can obtain substantially the same effect as the first embodiment.

### THIRD EMBODIMENT

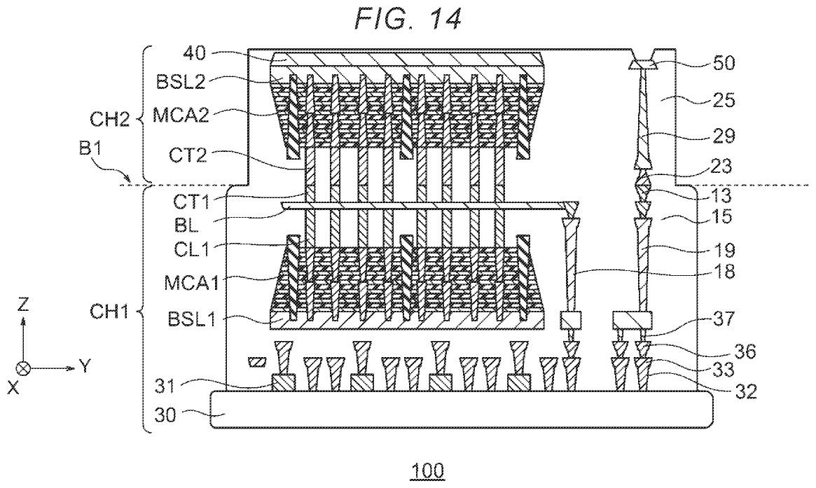

FIG. 14 is a cross-sectional view illustrating a configuration example of the semiconductor memory device 100 according to a third embodiment. According to the third embodiment, the CMOS chip CH3 and the first array chip CH1 are not bonded to each other, but rather a CMOS circuit is incorporated into the first array chip CH1. The first array chip CH1 includes the CMOS circuit below a memory cell array MCA1. Therefore, the transistor 31 of the CMOS circuit is formed on the substrate 30, and the memory cell array MCA1 is formed above the CMOS circuit. In general, the first array chip CH1 according to the third embodiment integrates the configurations of both the first array chip CH1 and the CMOS chip CH3 as described for the first embodiment with the transistors 31 being electrically connected to the source layer BSL1 via the vias 32 and 37 and the wiring 33 and 36.

The other configurations of the third embodiment may be the same as those of the first embodiment. Therefore, the third embodiment has the same effect as the first embodiment.

In the manufacturing method according to the third embodiment, in order to manufacture the first array chip CH1, the transistors 31 may be formed above the substrate 30 and then be covered with the interlayer insulating film 15, and further the source layer BSL1, the first memory cell array MCA1, the bit lines BL, and the like are formed above the transistors 31.

The other manufacturing steps of the third embodiment are the same as those of the first embodiment. Therefore, the third embodiment has substantially the same effect as the first embodiment. In addition, according to the third embodiment, a step of bonding the CMOS chip CH3 to the first array chip CH1 can be omitted. The third embodiment may be combined with the second embodiment. That is, the CMOS circuit may be incorporated into the second array chip CH2.

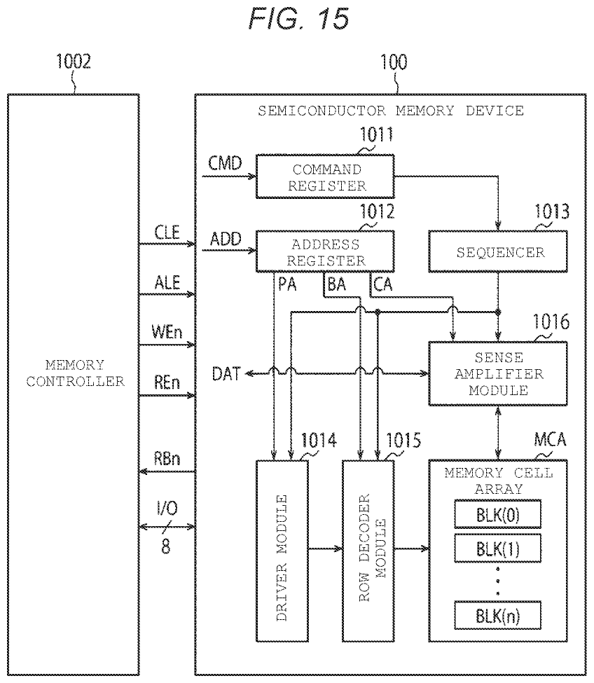

FIG. 15 is a block diagram illustrating a configuration example of a semiconductor memory device 100 to which any one of the described embodiments can be applied. The semiconductor memory device 100 is, for example, a NAND-type flash memory that can store data in a non-volatile manner and is controlled by an external memory controller 1002. The communication between the semiconductor memory device 100 and the memory controller 1002 supports, for example, the NAND interface standard.

As illustrated in FIG. 15, the semiconductor memory device 100 includes, for example, a memory cell array MCA, a command register 1011, an address register 1012, a sequencer 1013, a driver module 1014, a row decoder module 1015, and a sense amplifier module 1016.

The memory cell array MCA includes a plurality of blocks BLK(0) to BLK(n) (where n is an integer of 1 or more). The block BLK is a set of a plurality of memory cells that can store data in a non-volatile manner and is used, for example, as a unit of erasing data. In addition, a plurality of bit lines and a plurality of word lines are provided in the memory cell array MCA. Each memory cell is associated, for example, with one bit line and one word line. The detailed structure of the memory cell array MCA is described below.

The command register 1011 stores a command CMD received from the memory controller 1002 by the semiconductor memory device 100. The command CMD includes instructions, for example, for causing the sequencer 1013 to execute a read operation, a write operation, an erasing operation, and the like.

The address register 1012 stores address information ADD received from the memory controller 1002 by the semiconductor memory device 100. The address information ADD includes, for example, a block address BA, a page address PA, and a column address CA. For example, the block address BA, the page address PA, and the column address CA are used for selecting the block BLK, the word line, and the bit line.

The sequencer 1013 controls the entire operations of the semiconductor memory device 100. For example, the sequencer 1013 controls the driver module 1014, the row decoder module 1015, the sense amplifier module 1016, and the like based on the command CMD stored in the command register 1011 and executes the read operation, the write operation, the erasing operation, and the like.

The driver module 1014 generates voltages used for the read operation, the write operation, the erasing operation, and the like. Also, for example, the driver module 1014 applies the generated voltages to a signal line corresponding to the selected word line based on the page address PA stored in the address register 1012.

The row decoder module 1015 includes a plurality of row decoders. The row decoder selects one block BLK in the corresponding memory cell array MCA based on the block address BA stored in the address register 1012. Also, for example, the row decoder transmits the voltage applied to the signal line corresponding to the selected word line to the selected word line in the selected block BLK.

In the write operation, the sense amplifier module 1016 applies a desired voltage to each bit line according to write data DAT received from the memory controller 1002. In addition, in the read operation, the sense amplifier module 1016 determines data to be stored in the memory cell based on the voltage of the bit line and transmits the determination result to the memory controller 1002 as read data DAT.

The semiconductor memory device 100 and the memory controller 1002 may be integrated in one semiconductor device by the combination thereof. Examples of such a semiconductor device include a memory card such as an SDTM card or a solid-state drive (SSD).

FIG. 16 is a circuit diagram illustrating an example of a circuit configuration of a memory cell array MCA. One representative block BLK in the plurality of blocks BLK in the memory cell array MCA is depicted. As illustrated in FIG. 16, the block BLK includes a plurality of string units SU(0) to SU(k) (where k is an integer of 1 or more).

Each string unit SU includes a plurality of NAND strings NS respectively associated with the bit lines BL(0) to BL(m) (where m is an integer of 1 or more). Each NAND string NS includes, for example, memory cell transistors MT(0) to MT(15) and the select transistors ST(1) and ST(2). The memory cell transistor MT includes a control gate and a charge storage layer and stores data in a non-volatile manner. Each of the select transistors ST(1) and ST(2) is used for selecting the string unit SU during various operations.

In each NAND string NS, the memory cell transistors MT(0) to MT(15) are connected to each other in series. The drain of the select transistor ST(1) is connected to the associated bit line BL, and the source of the select transistor ST(1) is connected to one end of the memory cell transistors MT(0) to MT(15) connected to each other in series. The drain of the select transistor ST(2) is connected to the other end of the memory cell transistors MT(0) to MT(15) connected to each other in series. The source of the select transistor ST(2) is connected to a source line SL.

In the same block BLK, the control gates of the memory cell transistors MT(0) to MT(15) are commonly connected to the word line WL(0) to WL(15), respectively. The gates of the select transistors ST(1) in the string units SU(0) to SU(k) are commonly connected to the select gates SGD(0) to SGD(k), respectively. The gates of the select transistors ST(2) are commonly connected to the select gate line SGS.

In the circuit configuration of the memory cell array MCA described above, the bit line BL is shared by the NAND strings NS to which the same column address is allocated in each string unit SU. The source line SL is shared, for example, by the plurality of blocks BLK.

A set (group) of memory cell transistors MT connected to the same word line WL in a string unit SU is referred to as a cell unit CU. The storage capacity of the cell unit CU including the memory cell transistors MT each of which stores one bit of data is defined as “one page of data”. The cell unit CU may have a storage capacity of two or more pages of data according to the number of bits of data stored in each memory cell transistor MT.

The memory cell array MCA in the semiconductor memory device 100 is not limited to the circuit configuration described above. For example, the number of memory cell transistors MT and the select transistors ST(1) and ST(2) in each NAND string NS may be designed to be any number, respectively. The number of string units SU in each block BLK may be designed to be any number.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a first chip that includes a first memory cell array including a plurality of first memory cells and a first wiring layer electrically connected to the first memory cell array; and
a second chip that includes a second memory cell array electrically connected to the first wiring layer and including a plurality of second memory cells, wherein
the second chip is joined to the first chip at a first joining surface, and
the second memory cell array shares the first wiring layer of the first chip with the first memory cell array.

2. The semiconductor memory device according to claim 1, wherein
the first chip further includes a first pad electrically connected to the first wiring layer, and
the second chip further includes a second pad electrically connected to the first pad and the second memory cell array.

3. The semiconductor memory device according to claim 2, wherein, when viewed in plan view from a direction in which the first chip and the second chip are stacked, the first pad and the second pad are positioned at substantially the same positions.

4. The semiconductor memory device according to claim 3, wherein the first pad and the second pad are bonded to one another at the first joining surface.

5. The semiconductor memory device according to claim 4, further comprising:
a third chip that includes a plurality of transistors and a third pad electrically connected to one of the plurality of transistors, wherein
the third pad is bonded to a fourth pad at a second joining surface, and
the fourth pad is electrically connected to the first memory cell array of the first chip.

6. The semiconductor memory device according to claim 4, further comprising:
a third chip that includes a plurality of transistors and a third pad electrically connected to one of the plurality of transistors, wherein
the third pad is bonded to a fifth pad that is electrically connected to the second memory cell array of the second chip at a third joining surface.

7. The semiconductor memory device according to claim 1, wherein the first chip further includes a plurality of transistors below the first memory cell array.

8. The semiconductor memory device according to claim 1, wherein the first wiring layer comprises a plurality of bit lines shared by the first and second memory cell arrays.

9. The semiconductor memory device according to claim 8, wherein bit lines are not provided in the second chip.

10. A semiconductor memory device, comprising:
a first memory chip that includes a first memory cell array including a plurality of first memory cells and a plurality of bit lines above the plurality of first memory cells in a first direction and electrically connected to the first memory cells of the first memory cell array; and
a second memory chip bonded to the first memory chip, the second memory chip including a second memory cell array including a plurality of second memory cells, wherein
the plurality of bit lines is between the first and second memory arrays in the first direction, and
the plurality of bit lines is electrically connected to the second memory cells.

11. The semiconductor memory device according to claim 10, wherein
the first memory chip further includes a first pad electrically connected to a bit line in the plurality of bits lines, and
the second chip further includes a second pad electrically connecting to the first pad to second memory cells.

12. The semiconductor memory device according to claim 11, wherein, when viewed in plan view from the first direction, the first pad and the second pad are positioned at substantially the same positions.

13. The semiconductor memory device according to claim 11, further comprising:
a controller chip that includes a plurality of transistors, the controller chip being bonded to the first memory chip, wherein
the first memory chip is between the controller chip and the second memory chip in the first direction.

14. The semiconductor memory device according to claim 13, wherein electrical connections between the controller chip and the second memory chip extend through the first memory chip.

15. The semiconductor memory device according to claim 10, wherein the first memory chip further includes a plurality of transistors below the first memory cell array in the first direction.

16. The semiconductor memory device according to claim 15, wherein bit lines are not provided in the second memory chip.

17. The semiconductor memory device according to claim 10, wherein bit lines are not provided in the second memory chip.

18. A method for manufacturing a semiconductor memory device, the method comprising:
forming a first chip that includes a first memory cell array with a plurality of first memory cells and a first wiring layer including a plurality of bit lines electrically connected to the first memory cell array;
forming a second chip that includes a second memory cell array including a plurality of second memory cells without a wiring layer with a plurality of bit lines electrically connected to the second memory cells array; and
bonding the first chip and the second chip so that the plurality of bit lines in the first wiring layer are electrically connected to second memory cells in the second memory cell array.

19. The method according to claim 18, wherein the first chip further includes a plurality of transistors of a peripheral circuit for controlling the first and second memory cell arrays.

20. The method according to claim 18, further comprising:
bonding a third chip including a plurality of transistors of a memory controller for controlling the first and second memory cell arrays, wherein the first chip is between the second and third chips.
